(19) United States
(12) Patent Application Publication
(10) Pub. No.: US 2025/0336442 A1
(43) Pub. Date: Oct. 30, 2025

(54) CONTENT ADDRESSABLE MEMORY AND ITS OPERATION METHOD, PROCESSOR, AND MEMORY SYSTEM

(71) Applicant: Yangtze Memory Technologies Co., Ltd., Wuhan (CN)

(72) Inventor: Cheng CHANG, Wuhan (CN)

(21) Appl. No.: 18/899,834

(22) Filed: Sep. 27, 2024

(30) Foreign Application Priority Data
Apr. 29, 2024 (CN) 202410537604.3

(51) Int. Cl. G11C 15/04; G11C 11/418; G11C 11/419; H03K 19/21

(52) U.S. Cl. CPC G11C 15/04; G11C 11/418; G11C 11/419; H03K 19/21

(57) ABSTRACT

The present application proposes a content addressable memory including: memory cells coupled with each word line and a bit line bus; a timing control circuit configured to determine an operation mode including read, write, and compare modes and generate a control signal for a corresponding operation mode according to a received bus command; an address line control circuit configured to activate a corresponding word line and the bit line bus based on the control signal; and a processing and output circuit configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

### CROSS-REFERENCE TO RELATED APPLICATIONS

This application claims priority to Chinese Patent Application No. 202410537604.3, filed on Apr. 29, 2024, which is hereby incorporated by reference in its entirety.

### TECHNICAL FIELD

An implementation of the present application relates to the field of semiconductor technology, and particularly to a content addressable memory and its operation method, processor, and memory system.

### BACKGROUND

A content addressable memory (CAM) is a memory that addresses content. When performing content addressing, the CAM can automatically compare an input data item with all the data items stored in the CAM simultaneously, deciding whether the input data item matches the data items stored in the CAM. If they match, a matching success signal and a matching information corresponding to the data item are output. If they do not match, a matching failure signal is output. The content addressing time of the CAM still needs to be optimized.

### SUMMARY

An implementation of the present application proposes a content addressable memory and its operation method, processor, and memory system.

Firstly, an implementation of the present application provides a content addressable memory comprising: a plurality of word lines; a bit line bus; a plurality of memory cells coupled with each of the word lines and the bit line bus; a timing control circuit configured to determine an operation mode according to a received bus command and generate a control signal for a corresponding operation mode, the operation mode comprising a read mode, a write mode, and a compare mode; an address line control circuit coupled with the timing control circuit, the word lines and the bit line bus and configured to activate a corresponding word line and the bit line bus based on the control signal; and a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

In some implementations, the timing control circuit comprises: a timing generation circuit configured to determine the operation mode according to the received bus command and generate the control signal and a reset signal for the corresponding mode according to the determined operation mode; an address counting circuit coupled with the timing generation circuit and configured to receive a clock signal and the reset signal, and based on the reset signal, output a row address signal of a next row of a current processed row according to an edge change of the clock signal; and a word line decoding circuit coupled with the address counting circuit and configured to receive the row address signal outputted by the address counting circuit, decode a row address in the row address signal, and output the decoded signal.

In some implementations, the address line control circuit comprises: a word line control circuit coupled with the word line decoding circuit and configured to receive the decoded signal and generate a word line drive signal according to the decoded signal to activate the corresponding word line; and a data conversion circuit configured to receive the control signal for the corresponding mode, and according to the control signal for the corresponding mode, perform a conversion of data bit on read data in the read mode, perform a conversion of data bit and differential processing on data to be written in the write mode, and perform differential processing on data to be compared in the compare mode.

In some implementations, the processing and output circuit comprises: a processing circuit coupled with the bit line bus and the memory cells and configured to compare a first data to be compared inputted from the bit line bus with a second data already stored in the memory cells and output a data matching signal according to the compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and a decision circuit coupled with the processing circuit and configured to receive the data matching signal and output the compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

In some implementations, the processing circuit is further configured to: in the write mode, write the data to be written after being processed by the data conversion circuit to the memory cells coupled with an n-th word line to an (n+3)-th word line within four clock cycles, wherein data bits of the data to be written are m bits, data bits of the data to be written after being processed by the data conversion circuit are 2m bits, a first bit to an m-th bit and an (m+1)-th bit to a 2m-th bit of the second data respectively represent data stored in an (n+2)-th word line and the (n+3)-th word line, and an m-th bit and an (m+1)-th bit of the third data respectively represent data stored in the n-th word line and an (n+1)-th word line, where the m and the n are both natural numbers, and the m is a multiple of 8.

In some implementations, the processing circuit comprises: a first processing circuit coupled with the bit line bus and the memory cells and configured to compare the first data with the second data and output a matching signal according to the compare result in the compare mode, wherein according to the first data being the same as the second data, the matching signal outputted is in the first logical state, and according to the first data being different from the second data, the matching signal outputted is in the second logical state; and a second processing circuit coupled with the first processing circuit and configured to receive the matching signal and output the data matching signal according to the matching signal, wherein according to the matching signal being in the first logical state, the data matching signal outputted is the third data, and according to the matching signal being in the second logical state, the data matching signal outputted is the fourth data, and each bit of data of the fourth data is in the second logical state.

In some implementations, the first processing circuit comprises: a plurality of memory cell XOR circuits each coupled with the bit line bus, wherein each memory cell XOR circuit is coupled with one of the memory cells and configured to perform XOR processing on data inputted from the bit line bus with the data stored in the memory cells, and output an XOR result; and a first logic operation circuit coupled with the plurality of memory cell XOR circuits and configured to receive the XOR result outputted by each memory cell XOR circuit corresponding to the memory cells coupled with an (n+2)-th word line to an (n+3)-th word line, and performing a first logic operation on each XOR result to generate the matching signal.

In some implementations, the second processing circuit comprises: a plurality of memory cell inverting circuits, each of which is coupled with one of the memory cells and configured to perform a inverting processing on the data stored in the memory cells and output an inverted result; and a second logic operation circuit coupled with the plurality of memory cell inverting circuits and configured to receive the inverted result outputted by each memory cell inverting circuit corresponding to the memory cells coupled with the n-th word line to the (n+1)-th word line, and perform a second logic operation on each inverted result to generate the data matching signal.

In some implementations, the third data is storage address data corresponding to the second data.

In some implementations, the bit line bus comprises a first bit line bus and a first complementary bit line bus, and the memory cell comprises: a first transistor, a second transistor, a first inverter, and a second inverter, wherein: a control end of the first transistor is connected with the word line, a first controlled end of the first transistor is connected with the first bit line bus, and a second controlled end of the first transistor is connected with both of an input end of the first inverter and an output end of the second inverter; and a control end of the second transistor is connected with the word line, a first controlled end of the second transistor is connected with the first complementary bit line bus, and a second controlled end of the second transistor is connected with both of an output end of the first inverter and an input end of the second inverter.

Secondly, an implementation of the present application provides a processor comprising one or more content addressable memories, wherein the content addressable memory comprises: a plurality of word lines; a bit line bus; a plurality of memory cells coupled with each of the word lines and the bit line bus; a timing control circuit configured to determine an operation mode according to a received bus command and generate a control signal for a corresponding operation mode, the operation mode comprising a read mode, a write mode, and a compare mode; an address line control circuit coupled with the timing control circuit, the word lines and the bit line bus and configured to activate a corresponding word line and the bit line bus based on the control signal; and a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

In some implementations, the processor comprises a microprocessor unit MCU.

Thirdly, an implementation of the present application provides a memory system comprising: at least one memory device and a memory controller coupled with and controlling the memory device, wherein: the memory device comprises: a memory cell array and a peripheral circuit coupled with and controlling the memory cell array; at least one of the peripheral circuit or the memory controller comprises one or more processors comprising one or more content addressable memories, wherein the content addressable memory comprises: a plurality of word lines; a bit line bus; a plurality of memory cells coupled with each of the word lines and the bit line bus; a timing control circuit configured to determine an operation mode according to a received bus command and generate a control signal for a corresponding operation mode, the operation mode comprising a read mode, a write mode, and a compare mode; an address line control circuit coupled with the timing control circuit, the word lines and the bit line bus and configured to activate a corresponding word line and the bit line bus based on the control signal; and a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

Fourthly, an implementation of the present application provides another content addressable memory comprising: a plurality of word lines extending along a first direction; a bit line bus extending along a second direction, wherein the first direction is perpendicular to the second direction; a plurality of memory banks to which the bit line bus and each of the word lines are coupled, wherein the plurality of memory banks are arranged along the first direction and each memory bank comprises a plurality of memory cells arranged along the second direction; a timing control circuit located between two adjacent memory banks and configured to determine an operation mode according to a received bus command and generate a control signal for a corresponding operation mode, wherein the operation mode comprise a read mode, a write mode, and a compare mode; a plurality of address line control circuits each coupled with the timing control circuit, located at an edge of one memory bank, and configured to activate a corresponding word line and the bit line bus based on the control signal; and a processing and output circuit coupled with the bit line bus and configured to: read out data stored in the memory cells from the bit line bus in the read mode; write data to be written from the bit line bus to the memory cells in the write mode, and compare data to be compared inputted from the bit line bus with the data already stored in the memory cells and output a compare result in the compare mode.

In some implementations, the plurality of memory banks comprise a first memory bank to a 2p-th memory bank arranged along the first direction, wherein the p is a positive integer, and the bit line bus comprises 2p parts each of which is connected with one memory bank.

In some implementations, the timing control circuit is located between a p-th memory bank and a (p+1)-th memory bank.

In some implementations, the memory bank comprises 2q memory cells arranged along the second direction, wherein the q is a positive integer, and the processing and output circuit comprises: a processing circuit located on one side of the memory cells, coupled with the bit line bus and the memory cells, and configured to: compare a first data to be compared inputted from the bit line bus with a second data already stored in the memory cells and output a data matching signal according to a compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and a decision circuit located between a q-th memory bank and a (q+1)-th memory bank, coupled with the processing circuit, and configured to receive the data matching signal and output a compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

Fifthly, an implementation of the present application provides an operation method for a content addressable memory comprising: a plurality of word lines, a bit line bus, a plurality of memory cells coupled with each word line and the bit line bus, a timing control circuit, an address line control circuit coupled with the timing control circuit, the word lines, and the bit line bus, and a processing and output circuit; wherein the operation method comprises: the timing control circuit determining an operation mode according to a received bus command and generating a control signal for a corresponding operation mode, the operation mode comprising a read mode, a write mode, and a compare mode; the address line control circuit activating a corresponding word line and the bit line bus based on the control signal; and the processing and output circuit reading out data stored in the memory cells from the bit line bus in the read mode, writing data to be written from the bit line bus to the memory cells in the write mode, and comparing data to be compared inputted from the bit line bus with data already stored in the memory cells and outputting a compare result in the compare mode.

In some implementations, the timing control circuit comprises: a timing generation circuit, an address counting circuit, and a word line decoding circuit; the address line control circuit activating a corresponding word line and the bit line bus based on the control signal, comprising: the timing generation circuit determining the operation mode according to the received bus command and generating the control signal and a reset signal for the corresponding mode according to the determined operation mode; the address counting circuit receiving a clock signal and the reset signal, and based on the reset signal, outputting a row address signal of a next row of a current processed row according to an edge change of the clock signal; and the word line decoding circuit receiving the row address signal outputted by the address counting circuit, decoding a row address in the row address signal, and outputting the decoded signal.

In some implementations, the address line control circuit comprises: a word line control circuit and a data conversion circuit; the address line control circuit activating a corresponding word line and the bit line bus based on the control signal, comprising: the word line control circuit receiving the decoded signal, and generating a word line drive signal according to the decoded signal to activate the corresponding word line; and the data conversion circuit receiving the control signal for the corresponding mode, and according to the control signal for the corresponding mode, performing a conversion of data bit on read data in the read mode, performing a conversion of data bit and differential processing on data to be written in the write mode, and performing differential processing on data to be compared in the compare mode.

In some implementations, the processing and output circuit comprises: a processing circuit and a decision circuit; the and comparing data to be compared inputted from the bit line bus with data already stored in the memory cells and outputting a compare result in the compare mode, comprising: the processing circuit comparing a first data to be compared inputted from the bit line bus with a second data already stored in the memory cells and outputting a data matching signal according to the compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and the decision circuit receiving the data matching signal and outputting the compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

In some implementations, the writing data to be written from the bit line bus to the memory cells in the write mode, comprising: the processing circuit writing, in the write mode, the data to be written after being processed by the data conversion circuit to the memory cells coupled with an n-th word line to an (n+3)-th word line within four clock cycles, wherein data bits of the data to be written are m bits, data bits of the data to be written after being processed by the data conversion circuit are 2m bits, a first bit to an m-th bit and an (m+1)-th bit to a 2m-th bit of the second data respectively represent data stored in an (n+2)-th word line and the (n+3)-th word line, and an m-th bit and an (m+1)-th bit of the third data respectively represent data stored in the n-th word line and an (n+1)-th word line, where the m and the n are both natural numbers, and the m is a multiple of 8.

In some implementations, the processing circuit comprises: a first processing circuit and a second processing circuit; the comparing a first data to be compared inputted from the bit line bus with a second data already stored in the memory cells and outputting a data matching signal according to the compare result in the compare mode, comprising: the first processing circuit comparing the first data with the second data and outputting a matching signal according to the compare result in the compare mode, wherein according to the first data being the same as the second data, the matching signal outputted is in the first logical state, and according to the first data being different from the second data, the matching signal outputted is in the second logical state; and the second processing circuit receiving the matching signal and outputting the data matching signal according to the matching signal, wherein according to the matching signal being in the first logical state, the data matching signal outputted is the third data, and according to the matching signal being in the second logical state, the data matching signal outputted is the fourth data, and each bit of data of the fourth data is in the second logical state.

In some implementations, the first processing circuit comprises: a plurality of memory cell XOR circuits and a first logic operation circuit; the first processing circuit comparing the first data with the second data and outputting a matching signal according to the compare result in the compare mode, comprising: each memory cell XOR circuit performing an XOR processing on data inputted from the bit line bus with data stored in the memory cells, and outputting an XOR result; and the first logic operation circuit receiving the XOR result outputted by each memory cell XOR circuit corresponding to the memory cells coupled with an (n+2)-th word line to an (n+3)-th word line, and performing a first logic operation on each XOR result to generate the matching signal.

In some implementations, the second processing circuit comprises a plurality of memory cell inverting circuits and a second logic operation circuit; the second processing circuit outputting the data matching signal according to the matching signal, comprising: each memory cell inverting circuit performing an inverting processing on the data stored in the memory cells and outputting an inverted result; and the second logic operation circuit receiving the inverted result outputted by each memory cell inverting circuit corresponding to the memory cells coupled with the n-th word line to the (n+1)-th word line, and performing a second logic operation on each inverted result to generate the data matching signal.

In an implementation of the present application, the time for write, read, and compare operations of the content addressable memory is optimized, and existing design rules (such as the design rules of SRAM memory cells and page buffers) can be adopted. If the process allows, compressing the area of the content addressable memory can provide a more reasonable plan layout for the digital back-end. The implementation difficulty of the plan layout is not high, the labor time cost is low, and it is conducive to improving the utilization rate of the back-end area and fully utilizing winding resources.

### BRIEF DESCRIPTION OF DRAWINGS

FIG. 1 is a schematic diagram of a timing control circuit of a content addressable memory provided in an implementation of the present application;

FIG. 2 is a schematic diagram of an address counting circuit of the timing control circuit in FIG. 1;

FIG. 3 is a schematic diagram of an address line control circuit of a content addressable memory provided in an implementation of the present application;

FIG. 4 is a schematic diagram of a processing circuit of a content addressable memory provided in an implementation of the present application;

FIG. 5 is a schematic diagram of a decision circuit of a content addressable memory provided in an implementation of the present application;

FIG. 6A is a schematic diagram of a memory cell XOR circuit and a memory cell of a content addressable memory provided in an implementation of the present application;

FIG. 6B is a schematic diagram of a memory cell inverting circuit and a memory cell of a content addressable memory provided in an implementation of the present application;

FIG. 7 is a schematic diagram of a plane layout of a content addressable memory provided in an implementation of the present application;

FIG. 8 is a schematic diagram of a processor with a content addressable memory provided in an implementation of the present application; and

FIG. 9 is a schematic diagram of a memory system with a content addressable memory provided in an implementation of the present application.

### DETAILED DESCRIPTION

In the following, an example implementation of the present application will be described in more detail with reference to the accompanying drawings. Although example implementations of the present application are shown in the accompanying drawings, it should be understood that the present application can be implemented in various forms and should not be limited by the example implementations described herein. On the contrary, providing these implementations is to enable a more thorough understanding of the present application and to fully convey the scope of the present application to those skilled in the art.

In the following description, a large number of example details are provided to provide a more thorough understanding of the present application. However, it is evident to those skilled in the art that the present application can be implemented without one or more of these details. In other examples, in order to avoid confusion with this application, some well-known technical features in the art have not been described; that is to say, not all the features of the actual implementations are described here, and the well-known functions and structures are not described in detail.

In the accompanying drawings, for clarity, the dimensions of layers, regions, and components, as well as their relative dimensions, may be exaggerated. The same reference numbers indicate the same components throughout.

It should be understood that when a component or layer is described as “on”, “adjacent to”, “connected to” or “coupled to” another component or layer, it can be directly on, adjacent to, connected to or coupled to the another component or layer, or there can exist an intermediate component or layer. On the contrary, when a component is described as “directly on”, “directly adjacent to”, “directly connected to” or “directly coupled to” another component or layer, there does not exist an intermediate component or layer. It should be understood that although the terms first, second, third, etc. may be employed to describe at least one of various components, members, regions, layers, or parts, the at least one of these components, members, regions, layers, or parts should not be limited by these terms. These terms are only employed to distinguish one component, member, region, layer or part from another component, member, region, layer or part. Therefore, without departing from the teachings of this application, a first component, member, region, layer or part discussed below can be represented as a second component, member, region, layer or part. When discussing the second component, member, region, layer or part, it does not necessarily mean that there necessarily exists a first component, member, region, layer or part.

The purpose of the terms used here is only to describe example implementations and is not to limit this application. When used here, “an”, “a”, and “said/the” in a singular form are also intended to comprise a plural form, unless the context clearly indicates otherwise. It should also be understood that at least one of the term “consist of” or “comprises”, when used in this description, determines the presence of at least one of said features, integers, steps, operations, components, or members, but do not exclude the presence or addition of at least one of one or more other features, integers, steps, operations, components, members, or groups. When used here, the term “at least one of” comprises any and all combinations of related listed items.

In order to make the characteristics and technical content of the implementations of the present application be understood in more detail, a detailed explanation of the implementations of the present application will be given in conjunction with the accompanying drawings in the following. The accompanying drawings are for reference only and are not intended to limit the implementations of the present application.

The content addressable memory is a memory that addresses content, similar to a random access memory (RAM), and has the function of reading and writing data according to the address, and also has the function of retrieving input data. When the content addressable memory is used as the RAM, data can be continuously written and read according to the start address; when the content is addressed, it can be compared with stored data. If the data already exists in the content addressable memory, a matching success signal and new data corresponding to the data are output. Conversely, if the data is not saved in the content addressable memory, a matching failure signal is output. However, the time required for write, read, and compare operations of the content addressable memories still needs to be optimized.

In view of this, the implementations of the present application propose a content addressable memory device and its operation method, processor, and memory system.

Firstly, an implementation of the present application provides a content addressable memory comprising: a plurality of word lines; a bit line bus; a plurality of memory cells coupled with each of the word lines and the bit line bus; a timing control circuit configured to determine an operation mode according to a received bus command and generate a control signal for a corresponding operation mode, the operation mode comprising a read mode, a write mode, and a compare mode; an address line control circuit coupled with the timing control circuit, the word lines and the bit line bus and configured to activate a corresponding word line and the bit line bus based on the control signal; and a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

Here and below, the word line is referred to as wl (or row), the word line address can also be referred to as a row address, the bit line is referred to as BL (or column), and the bit line address can also be referred to as a column address,

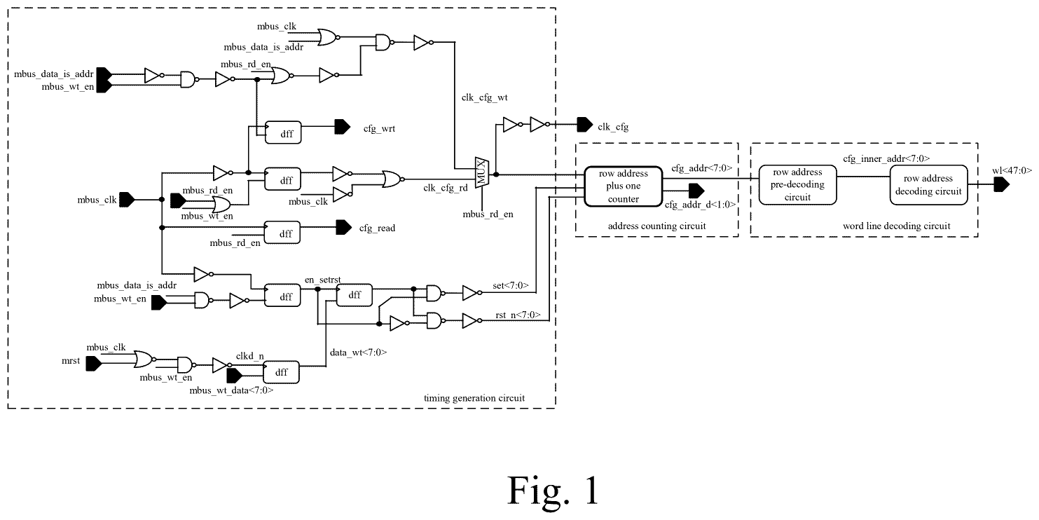

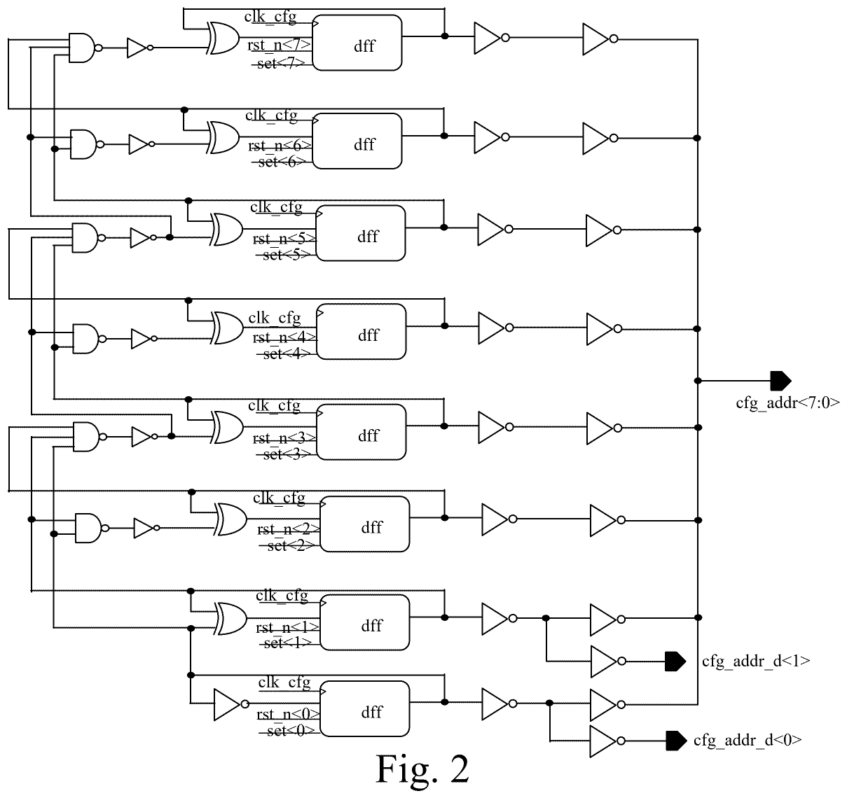

Referring to FIGS. 1 and 2, in some implementations, the timing control circuit comprises: a timing generation circuit configured to determine the operation mode according to the received bus command and generate the control signal and a reset signal for the corresponding mode according to the determined operation mode; an address counting circuit coupled with the timing generation circuit and configured to receive a clock signal and the reset signal, and based on the reset signal, output a row address signal of a next row of a current processed row according to an edge change of the clock signal; and a word line decoding circuit coupled with the address counting circuit and configured to receive the row address signal outputted by the address counting circuit, decode a row address in the row address signal, and output the decoded signal.

The timing control circuit is mainly configured to control the write, read, or compare operations of data stored in the content addressable memory by the bus signal mbus. The bus signal mbus can comprise a bus clock signal mbus_clk, the bus data being the address signal mbus_data_is_addr, a bus read enable signal mbus_rd_en, a bus write enable signal mbus_wt_en, and a bus write data signal mbus_wt_data<7:0>.

The timing generation circuit can generate an internal timing according to a MBus (meter bus) operating protocol, for example an enable signal for counter reset/initial state, counting clock, read/write word line enabling, pre-charge, etc.

Referring to FIG. 1, in some implementations, the timing generation circuit comprises a logic gate circuit (such as a NOT gate, NAND gate, or NOT gate), a data trigger dff, and a multiplexer MUX. For example, a clock end of a data trigger dff receives the bus clock signal mbus_clk, a data end receives the bus write enable signal mbus_wt_en, and an output end outputs a read mode signal cfg_read. For example, a first input end of the multiplexer MUX receives a write mode clock signal clk_cfg_wt, a second input end receives a read mode clock signal clk_cfg_rd, a control end receives a bus write enable signal mbus_wt_en, and a output end selects either a write mode clock signal clk_cfg_wt or a read mode clock signal clk_cfg_rd to output.

For example, the timing generation circuit is configured to determine the operation mode according to a bus command, comprising determining the read mode, write mode, or compare mode according to the bus signal mbus.

For example, the timing generation circuit is configured to, according to a determined operation mode, generate a control signal for the corresponding mode, comprising: generating a write mode signal cfg_wrt/a read mode signal cfg_read according to the bus signal mbus, the write mode signal cfg_wrt/the read mode signal cfg_read being transmitted to a memory cell of the content addressable memory for controlling the write mode/read mode of the memory cell of the content addressable memory. For example, the read mode signal cfg_read is generated according to the bus clock signal mbus_clk and the bus read enable signal mbus_rd_en, the write mode signal cfg_wrt is generated according to the bus clock signal mbus_clk, the bus data being address signal mbus_data_is_addr, and the bus write enable signal mbus_wt_en, and the write mode signal cfg_wrt/the read mode signal cfg_read is transmitted to each memory bank to control the write/read mode of the memory bank.

For example, the timing generation circuit is configured to, according to the determined operation mode, generate a reset signal of a corresponding mode, comprising: generating a reset signal set<7:0>/rst_n<7:0> according to the bus clock signal mbus_clk, the bus data being address signal mbus_data_is_addr, the bus write enable signal mbus_wt_en, and the bus write data signal mbus_wt_data<7:0>.

For example, the timing generation circuit being configured to, according to a determined operation mode, generate a reset signal of the corresponding mode, further comprises: generating the read mode clock signal clk_cfg_rd according to the bus clock signal mbus_clk, the bus read enable signal mbus_rd_en, and the bus write enable signal mbus_wt_en. The write mode clock signal clk_cfg_wt is generated according to the bus clock signal mbus_clk, the bus data being address signal mbus_data_is_addr, the bus read enable signal mbus_rd_en, and the bus write enable signal mbus_wt_en. The write mode clock signal clk_cfg_wt/the read mode clock signal clk_cfg_rd is configured to generate a row address plus one (+1) clock signal and a mode clock signal clk_cfg.

The address counting circuit can have an initial address enable function, which triggers an address plus one (+1) operation on a positive edge (rising edge) of the clock, and its output address is used for word line decoding.

Referring to FIG. 1, in some implementations, the address counting circuit comprises a row address plus one counter.

Referring to FIG. 2, in some implementations, the row address plus one counter comprises a logic gate circuit (such as an NAND gate, NOT gate, XOR gate) and a data trigger dff. For example, the clock end of the data trigger dff receives the mode clock signal clk_cfg, the first data end receives a first feedback signal, the second data end receives a reset signal rst_n<0>, the third data end receives a reset signal set<0>, and the output end outputs a row address signal cfg_addr<7:0> of the next row and an odd or even number judgement signal cfg_addr_d<0>, where the first feedback signal is an inverted signal of the output signal of a data trigger dff. For example, the clock end of another data trigger dff receives the mode clock signal clk_cfg, the first data end receives a second feedback signal, the second data end receives a reset signal rst_n<1>, the third data end receives a reset signal set<1>, and the output end outputs the row address signal cfg_addr<7:0> of the next row and an odd or even number judgement signal cfg_addr_d<1>, where the second feedback signal is a signal obtained by an XOR operation between the output signal of one data trigger dff and the output signal of another data trigger dff.

For example, the address counting circuit decides a first read/write address from the bus data being address signal mbus_data_is_addr, generates the reset signal set<7:0>/rst_n<7:0> to reset the data trigger, and then generates the triggering of the row address+1 by the mode clock signal clk_cfg which is operating along the triggering of the row address+1, generates the row address signal cfg_addr<7:0> of the next row and the odd or even number judgement signal cfg_addr<1>. The row address signal cfg_addr<7:0> of the next row is used for decoding of the next row.

For example, the address counting circuit is configured to output a row address signal of the next row of the current processed row according to the clock signal and the reset signal, comprising outputting the row address signal cfg_addr<7:0> of the next row of the current processed row and the odd or even number judgement signal cfg_addr<1:0> according to the write mode clock signal clk_cfg_wt/the read mode clock signal clk_cfg_rd and the reset signal set<7:0>/rst_n<7:0>. A combination of the odd or even number judgement signal cfg_addr<1:0> is used for deciding an odd or even number byte.

The word line decoding circuit generates a row address decoded signal from the row address signal, and the row address decoded signal is used to select one of the word lines.

Referring to FIG. 1, in some implementations, the word line decoding circuit comprises a row address pre-decoding circuit and a row address decoding circuit. The row address pre-decoding circuit receives input data from the address counting circuit and performs address re-mapping; the row address decoding circuit parses the corresponding word line to be enabled according to the re-mapped address.

For example, the word line decoding circuit comprises a row address pre-decoding circuit coupled with the timing generation circuit and a row address decoding circuit coupled with the row address pre-decoding circuit. The row address pre-decoding circuit is configured to generate a row address pre-decoded signal according to the row address signal outputted by the address counting circuit, and the row address decoding circuit is configured to generate a row address decoded signal according to the row address pre-decoded signal. For example, the row address pre-decoding circuit generates a row address pre-decoded signal cfg_inner_addr<7:0> according to the row address signal of the next row output by the address counting circuit, and the row address decoding circuit generates a row address decoded signal wl<47:0> according to the row address pre-decoded signal cfg_inner_addr<7:0>. The row address decoded signal wl<47:0> can be employed to select one of the first word line wl<0> to the 48-th word line wl<47>.

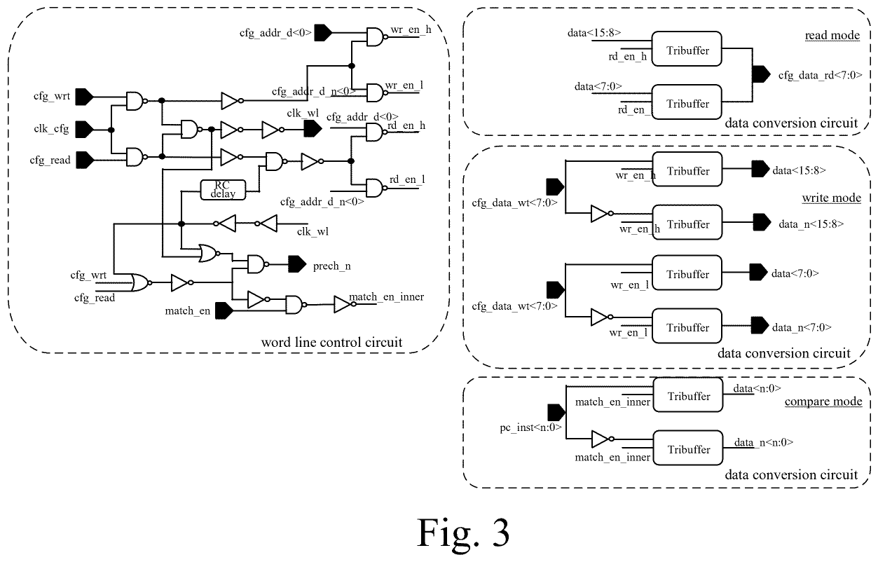

Referring to FIG. 3, in some implementations, the address line control circuit comprises: a word line control circuit coupled with the word line decoding circuit and configured to receive the decoded signal and generate a word line drive signal according to the decoded signal to activate the corresponding word line; a data conversion circuit configured to receive the control signal for the corresponding mode, and according to the control signal for the corresponding mode, perform a conversion of data bit on read data in the read mode, perform a conversion of data bit and differential processing on data to be written in the write mode, and perform differential processing on data to be compared in the compare mode.

The address line control circuit comprises a global word line generation circuit and a bit line bus control circuit and generates a row address decoded signal and a bit line bus decoded signal for write, read, or compare operations. In some implementations, the address line control circuit is configured to generate a global word line enable pulse through a clock signal, and the bit line bus can write/read data of the memory cell, or input data to be compared through a bit line to compare with the stored content.

Referring to FIG. 3, in some implementations, the word line control circuit comprises a logic gate circuit (such as a NOT gate, NAND gate, or NOR gate) and a delay circuit RC delay. For example, a comparison enable internal signal match_en_inner is generated according to a comparison enable signal match_en, the mode clock signal clk_cfg, the write mode signal cfg_wrt, and the read mode signal cfg_read.

For example, the word line control circuit is configured to: generate the comparison enable internal signal match_en_inner according to the row clock signal clk_wl, the comparison enable signal match_en, the mode clock signal clk_cfg, the write mode signal cfg_wrt, and the read mode signal cfg_read; generate a write enable logic high signal wr_en_h/a write enable logic low signal wr_en_l according to the row clock signal clk_wl, the mode clock signal clk_cfg, the write mode signal cfg_wrt, and the odd or even number judgement signal cfg_addr_d<0>/an inverted signal of the odd or even number judgement signal cfg_addr_d_n<0>; and generate a read enable logic high signal rd_en_h/a read enable logic low signal rd_en_l according to the row clock signal clk_wl, the mode clock signal clk_cfg, the read mode signal cfg_read, and the odd or even number judgement signal cfg_addr_d<0>/the inverted signal of the odd or even number judgement signal cfg_addr_d_n<0>.

Referring to FIG. 3, in some implementations, the data conversion circuit comprises a logic gate circuit (such as a NOT gate) and a tri-state buffer Tribuffer. When a control end of the three-state buffer is enabled, the device achieves normal signal transmission. When the control end of the three-state buffer is not enabled, its output is in a high resistance state, which is equivalent to disconnecting the circuit connected with the three-state buffer. For example, in the compare mode, an input end of a tri-state buffer Tribuffer receives an external input data signal that needs to be compared pc_inst<n:0>, its control end receives the comparison enable internal signal match_en_inner, and its output end outputs the data signal data<n:0>. An input end of another tri-state buffer Tribuffer receives an inverted signal of the external input data signal that needs to be compared pc_inst<n:0>, its control end receives the comparison enable internal signal match_en_inner, and its output end outputs an inverted signal data_n<n:0> of the data signal.

For example, the data conversion circuit is configured to: in the write mode, generate a stored data signal data<15:8> according to a data signal to be written cfg_data_wt<7:0> and the write enable logic high signal wr_en_h, generate an inverted signal data_n<15:8> of the stored data signal according to an inverted signal of the data signal to be written cfg_data_wt<7:0> and the write enable logic high signal wr_en_h to be written, generate the stored data signal data<7:0> according to the data signal to be written cfg_data_wt<7:0> and the write enable logic low signal wr_en_l, and generate the inverted signal data_n<7:0> of the stored data signal according to the inverted signal of the data signal to be written cfg_data_wt<7:0> and the write enable logic low signal wr_en_l. The stored data signals data<7:0> and data<15:8> are configured to be written to the memory cell.

For example, the data conversion circuit is configured to: in the read mode, generate a read data signal cfg_data_rd<7:0> according to the stored data signal data<7:0> and the read enable logic low signal rd_en_l, as well as according to the stored data signal data<15:8> and the read enable logic high signal rd_en_h.

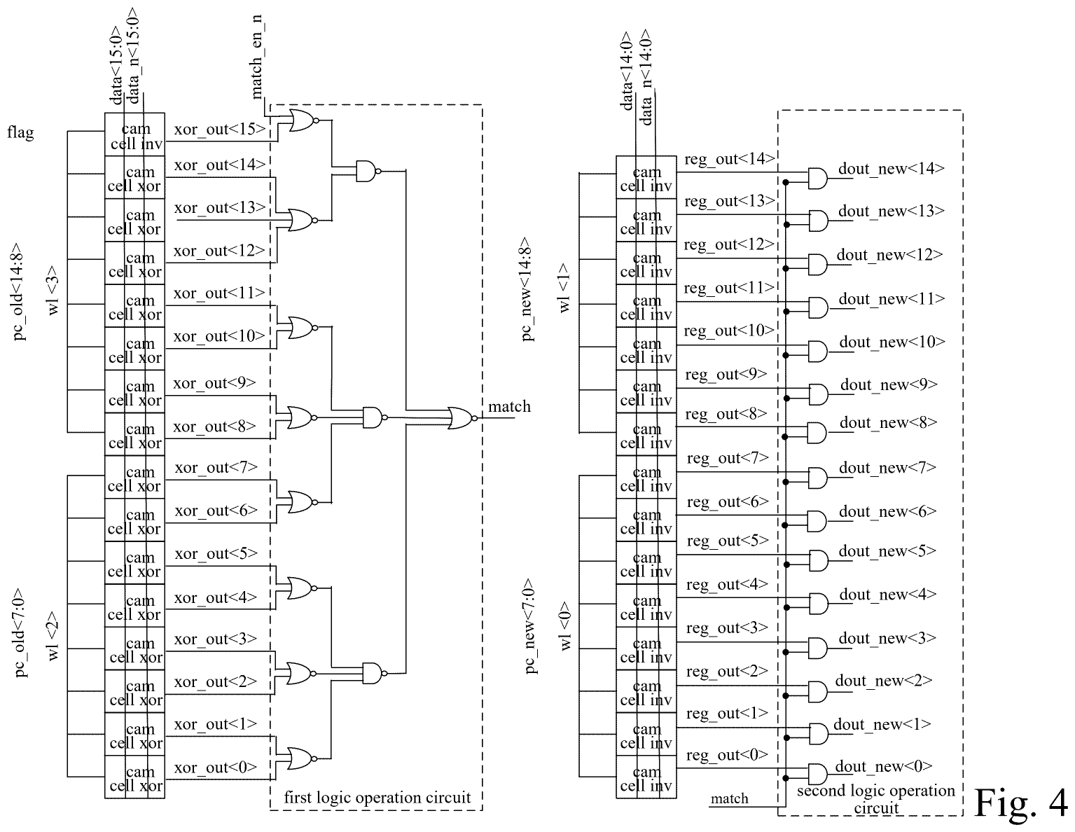

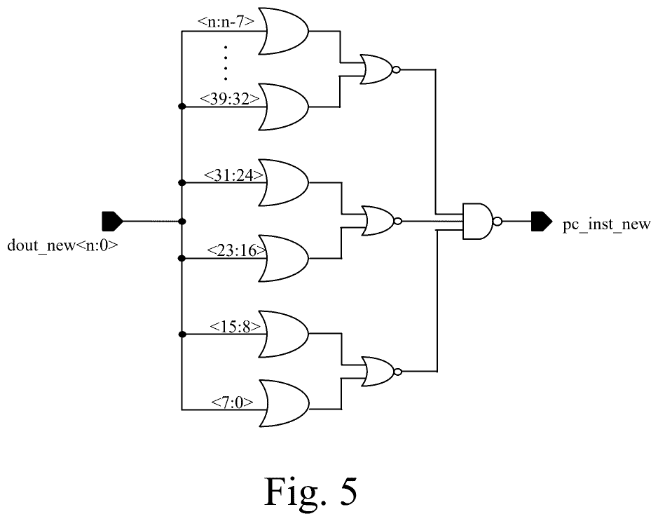

For example, the data conversion circuit is configured to: in the compare mode, generate a data signal data<n:0> according to the external input data signal that needs to be compared pc_inst<n:0> and the comparison enable internal signal match_en_inner, and generate an inverted signal data_n<n:0> of the data signal according to an inverse signal of the external input data signal that needs to be compared pc_inst<n:0> and the comparison enable internal signal match_en_inner. The data signal data<n:0> is configured to compare with the stored data (such as the stored data signals data<7:0> and data<15:8>). If the data already exists in the content addressable memory, a matching success signal and new data corresponding the data are output. Conversely, if the data is not saved in the content addressable memory, a matching failure signal is output. The related sections of FIGS. 4 and 5 below will provide a detailed introduction to the comparison between the data signal data<n:0> and the stored data.

Referring to FIGS. 4 and 5, in some implementations, the processing and output circuit comprises: a processing circuit coupled with the bit line bus and the memory cells and configured to compare a first data to be compared inputted from the bit line bus with a second data already stored in the memory cells and output a data matching signal according to the compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and a decision circuit coupled with the processing circuit and configured to receive the data matching signal and output the compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

The first data can be represented as the data signal data<n:0> and its inverted signal data_n<n:0>. In the following explanation, the first data can also be briefly referred to as the data signal to be compared data<n:0>. The second data can be represented as the stored data signals for comparison pc_old<7:0>, pc_old<14:8>, and pc_old<15>. In the following explanation, the second data can also be briefly referred to as old data signals pc_old<7:0> and pc_old<14:8>, and an identification signal pc_old<15> (or identification signal flag). The third data can be represented as new data signals pc_new<7:0> and pc_new<14:8> corresponding to the old data signals pc_old<7:0> and pc_old<14:8>. In the following explanation, the third data can also be briefly referred to as the new data signals pc_new<7:0> and pc_new<14:8>. The fourth data can be configured to indicate whether to output the new data signals pc_new<7:0> and pc_new<14:8> according to whether the matching signal match is enabled or not. In the following explanation, the fourth data can also be referred to as data matching signals dout_new<7:0> and dout_new<14:8>.

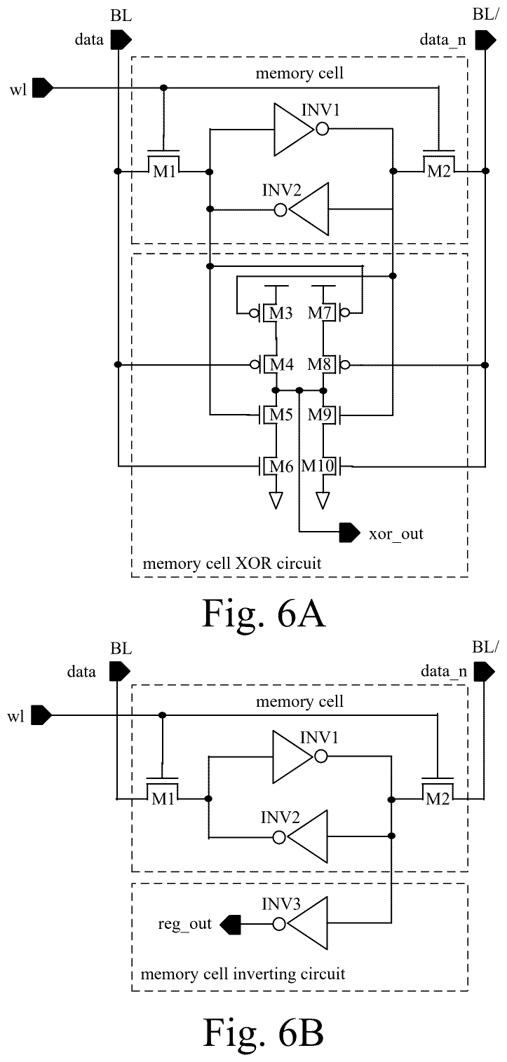

It should be noted that FIG. 4 also illustrates a memory cell coupled with a memory cell XOR circuit, a circuit comprising the memory cell XOR circuit and the memory cell coupled with the memory cell XOR circuit hereinafter is briefly referred to as the XOR cell circuit cam cell xor. FIG. 6A shows an example structure of the XOR unit circuit cam cell xor. FIG. 4 also shows a memory cell coupled with a memory cell inverting circuit, a circuit comprising the memory cell inverting circuit and the memory cell coupled with the memory cell inverting circuit hereinafter is briefly referred to as the inverting cell circuit cam cell inv. FIG. 6B shows an example structure of the inverting cell circuit cam cell inv.

Referring to FIG. 4, in some implementations, the processing circuit comprises a first processing circuit comprising a memory cell XOR circuit and a logic gate circuit (such as an NOR gate, an NAND gate), and a second processing circuit comprising a memory cell inverting circuit and a logic gate circuit (such as an AND gate).

In some implementations, the processing circuit is configured to: in the write mode, write the data signal to be written into a memory cell (comprising at least one of a memory cell coupled with a memory cell XOR circuit or a memory cell coupled with a memory cell inverting circuit) through a bit line bus; alternatively, in the read mode, read out the data signals stored in the memory cell (comprising at least one of a memory cell coupled with the memory cell XOR circuit or a memory cell coupled with the memory cell inverting circuit) from the corresponding memory cell through the bit line bus; alternatively, in the compare mode, transmit the data signal to be compared to the memory cell XOR circuit through the bit line bus, and match it with the second data stored in the memory cell (comprising the memory cell coupled with the memory cell XOR circuit) to output a data matching signal. The data matching signal is configured to determine whether to output the third data stored in the memory cell (comprising the memory cell coupled with the memory cell inverting circuit). If the matching succeeds, the data matching signal outputted by the second processing circuit is in the first logical state, that is, a new data corresponding to the data to be compared (which can be understood as the data stored in the memory cell of the second processing circuit). If the matching fails, the data matching signal outputted by the second processing circuit is in the second logical state, shown as a matching failed signal.

Referring to FIG. 5, in some implementations, the decision circuit comprises a combination logic comprising logic gate circuits (such as OR gate, NOR gate, and NAND gate).

In some implementations, the decision circuit is configured to summarize and output all data matching signals output by the processing circuit, and output a compare result. If the compare result is in the first logical state, the compare result indicates that the comparison succeeds, and the compare result is a new data corresponding to the data signal to be compared (which can be understood as data stored in the memory cell of the second processing circuit); and if the compare result is in the second logical state, the compare result indicates that the comparison has failed.

In some implementations, the data matching signal dout_new<n:0> received by the decision circuit is divided into a plurality of clock cycles and transmitted to the output end of the decision circuit, and is summarized as the compare result pc_inst_new to output. For example, the data matching signal dout_new<7:0> and dout_new<14:8> can be divided into two clock cycles and transmitted to the output end of the decision circuit, and is summarized as the compare result pc_inst_new to output. In some implementations, the number of data bits transmitted per clock cycle may be the same, for example, 8 bits of data can be transmitted per clock cycle. It should be noted that the 8 bits of data transmitted in one clock cycle is the data matching signal dout_new<7:0>, while the 8 bits of data transmitted in another clock cycle comprises 7 bits of data matching signal dout_new<14:8> and one bit of default data dout_new<15>, wherein the one bit of default data dout_new<15> can be missing, discarded, or set to the default value.

In some implementations, the OR gate shown in FIG. 5 has a plurality of inputs, for example, the OR gate has 8 inputs that respectively receive each bit of the 8 bits of data matching signal dout_new<7:0>.

Referring to FIG. 4, in some implementations, the processing circuit is further configured to: in the write mode, write the data to be written after being processed by the data conversion circuit to the memory cells coupled with an n-th word line to an (n+3)-th word line within four clock cycles, wherein data bits of the data to be written are m bits, data bits of the data to be written after being processed by the data conversion circuit are 2m bits, a first bit to an m-th bit and an (m+1)-th bit to a 2m-th bit of the second data respectively represent data stored in an (n+2)-th word line and the (n+3)-th word line, and an m-th bit and an (m+1)-th bit of the third data respectively represent data stored in the n-th word line and an (n+1)-th word line, where the m and the n are both natural numbers, and the m is a multiple of 8.

The data bits of the data to be written being m bits can be represented as the data signal to be written cfg_data_wt<7:0>. The data bits of the data to be written after being processed by the data conversion circuit being 2m bits can be represented as the stored data signals data<7:0> and data<15:8>. The third data is new data corresponding to the second data. For example, the second data can be represented as the stored data signals for comparison pc_old<7:0> and pc_old<14:8>, and an identification signal pc_old<15>, while the third data represents the stored new data signals pc_new<7:0>, pc_new<14:8> corresponding to the second data, and one default data pc_new<15> (not shown in FIG. 4). Here, the one bit of default data pc_new<15> is the data corresponding to the identification signal pc_old<15>, which can be missing, discarded, or set as the default value.

The n-th to (n+3)th word lines can be illustrated as the first word line wl<0>, the second word line wl<1>, the third word line wl<2>, and the fourth word line wl<3>. The first word line wl<0> is coupled with 8 memory cells for storing new data signal pc_new<7:0>, the second word line wl<1> is coupled with 8 memory cells for storing 7 bits of new data signal pc_new<14:8> and 1 bit of default data pc_new<15> (not shown in FIG. 4), the third word line wl<2> is coupled with 8 memory cells for storing the new data signal pc_old<7:0>, and the fourth word line wl<3> is coupled with 8 memory cells for storing the new data signal pc_old<14:8> and the identification signal pc_old<15>, wherein the identification signal pc_old<15> is configured to identify whether data has be written into the memory cells coupled with the first word line wl<0>, the second word line wl<1>, the third word line wl<2>, and the fourth word line wl<3>.

The processing circuit is configured to: in the write mode, with a data signal cfg_data_wt<7:0> to be written being the second data, generate the stored data signals data<7:0> and data<15:8> according to the data signal cfg_data_wt<7:0> to be written, wherein the stored data signals are written in two clock cycles to the 8 memory cells coupled with the third word line wl<2> and the 8 memory cells coupled with the fourth word line wl<4>, respectively, as the stored old data signal pc_old<7:0>, as well as the pc_old<14:8> and the identification signal pc_old<15>, and wherein the stored data signal data<15> is used as an identification signal flag; with another data signal to be written cfg_data_wt<7:0> being the third data, generate the stored data signals data<7:0> and data<15:8> according to the data signal to be written cfg_data_wt<7:0>, wherein the stored data signals are written in two clock cycles to the 8 memory cells coupled with the third word line wl<2> and the 8 memory cells coupled with the fourth word line wl<4>, respectively, as the stored new data signals pc_new<7:0>, pc_new<14:8>, and one bit of default data pc_new<15>, wherein the one bit of default data pc_new<15> corresponds to the identification signal flag, which can be missing, discarded, or set as the default value.

Referring to FIG. 4, in some implementations, the processing circuit comprises: a first processing circuit coupled with the bit line bus and the memory cells and configured to compare the first data with the second data and output a matching signal according to the compare result in the compare mode, wherein according to the first data being the same as the second data, the matching signal outputted is in the first logical state, and according to the first data being different from the second data, the matching signal outputted is in the second logical state; and a second processing circuit coupled with the first processing circuit and configured to receive the matching signal and output the data matching signal according to the matching signal, wherein according to the matching signal being in the first logical state, the data matching signal outputted is the third data, and according to the matching signal being in the second logical state, the data matching signal outputted is the fourth data, and each bit of data of the fourth data is in the second logical state.

For example, the first data is the data signal to be compared data<15:0>. The second data comprises the old data signals pc_old<7:0> and pc_old<14:8>, as well as the identification signal pc_old<15>. The third data comprises the new data signals pc_new<7:0> and pc_new<14:8>, as well as a bit of default data pc_new<15> (as shown in FIG. 4). The fourth data comprises the data matching signal dout_new<7:0>, as well as dout_new<14:8> and the data matching signal dout_new<15> corresponding to one bit of default data dout_new<15> (not shown in FIG. 4).

The first processing circuit is configured to: in the compare mode, compare the data signal to be compared data<15:0> with the old data signals pc_old<7:0>, pc_old<14:8>, and the identification signal pc_old<15>; output the matching signal match according to the compare result; wherein according to the data signal data<15:0> to be compared being the same as the old data signals pc_old<7:0>, pc_old<14:8>, and the identification signal pc_old<15>, the matching signal outputted match is in the first logical state, for example, the matching signal match is at the logic high level, and according to the data signal data<15:0> to be compared being different from the old data signals pc_old<7:0>, pc_old<14:8>, and the identification signal pc_old<15>, the matching signal outputted match is in the second logical state, for example, the matching signal match is at the logic low level.

The second processing circuit is configured to: in the compare mode, according to the matching signal match being in the first logic state, for example, the matching signal match being at the logic high level, output the stored new data signals pc_new<7:0> and pc_new<14:8>, that is, outputting the data matching signals dout_new<7:0> and dout_new<14:8>, and according to the matching signal match being in the second logical state, for example, the matching signal match being at the logic low level, not output the stored new data signals pc_new<7:0> and pc_new<14:8>, that is, each bit of the data matching signal outputted dout_new<7:0> and dout_new<14:8> is at the logic low level.

Referring to FIGS. 4 and 6A, in some implementations, the first processing circuit comprises: a plurality of memory cell XOR circuits each coupled with the bit line bus, wherein each memory cell XOR circuit is coupled with one of the memory cells and configured to perform XOR processing on data inputted from the bit line bus with the data stored in the memory cells, and output an XOR result xor_out; and a first logic operation circuit coupled with the plurality of memory cell XOR circuits and configured to receive the XOR result xor_out outputted by each memory cell XOR circuit corresponding to the memory cells coupled with an (n+2)-th word line to an (n+3)-th word line, and performing a first logic operation on each XOR result to generate the matching signal match.

In some implementations, the memory cell XOR circuit is configured to: in the compare mode, the fourth word line wl<3> being enabled, receive the stored data pc_old<14> of the memory cell, as well as the data data<14> inputted from the bit line bus, and output the XOR result xor_out<14> at the output end. The input end of the first logic operation circuit receives the XOR result xor_out<14>, and outputs the matching signal match at the output end.

In some implementations, the memory cell XOR circuit is configured: in the compare mode, the fourth word line wl<3> being enabled, receive the identification signal pc_old<15> of the memory cell, and receive the data data<15> inputted from the bit line bus, output the XOR result xor_out<15> at the output end. One input end of the first logic operation circuit receives the XOR result xor_out<15>, the other input end receives an inverted signal match_en_n of the comparison enable signal, and outputs the matching signal match at the output end.

In some implementations, the first logic operation circuit comprises multi-stage gate circuits cascaded. For example, the first logic operation circuit comprises a first stage gate circuit comprising a plurality of NOR gates, a second stage gate circuit comprising a plurality of NAND gates, and a third stage gate circuit comprising one NOR gate, and the first stage gate circuit, the second stage gate circuit, and the third stage gate circuit are cascaded in sequence. The first stage gate circuit receives the XOR result xor_out<15:0> and the inverted signal match_en_n of the comparison enable signal, and the third stage gate circuit outputs the matching signal match.

Referring to FIGS. 4 and 6B, in some implementations, the second processing circuit comprises: a plurality of memory cell inverting circuits, each of which is coupled with one of the memory cells and configured to perform a inverting processing on the data stored in the memory cells and output an inverted result reg_out; and a second logic operation circuit coupled with the plurality of memory cell inverting circuits and configured to receive the inverted result reg_out outputted by each memory cell inverting circuit corresponding to the memory cells coupled with the n-th word line to the (n+1)-th word line, and perform a second logic operation on each inverted result to generate the data matching signaldout_new.

In some implementations, one memory cell inverting circuit is configured to: in the compare mode, the second word line wl<1> being enabled, receive the inverted signal of the stored data pc_new<13> of the memory cell, invert this inverted signal and output the inverted result reg_out<13>, wherein the inverted result reg_out<13> is received at a first input end of an AND gate of the second logic operation circuit, the matching signal match is received at the second input end, and the data matching signal dout_new<13> is output at the output end.

In some implementations, the second logic operation circuit comprises a plurality of AND gates. The first input of each AND gate receives one bit of data of the inverted result (for example, the inverted result reg_out<13>), the second input of each AND gate receives the matching signal match, and the output end outputs one bit of data of the data matching signal (for example, the data matching signal dout_new<13>).

In some implementations, the third data is the storage address data corresponding to the second data.

For example, the second data represents the storage address (address signal), and the third data represents the data corresponding to the storage address (data signal), that is, the storage address data. For example, according to the data signal input from external that needs to be compared being the input address signal, the data signal stored for comparison being the storage address signal, the storage address data signal corresponding to the storage address signal is stored. In the compare mode, the input address signal is matched with the storage address signal. If the match is successful, the storage address data signal corresponding to the storage address signal is output. Otherwise, the matching failure signal is output.

Referring to FIG. 6A, in some implementations, the bit line bus comprises a first bit line bus BL and a first complementary bit line bus BL/; the memory cell comprises: a first transistor M1, a second transistor M2, a first inverter INV1, and a second inverter INV2, wherein a control end of the first transistor M1 is connected with the word line wl, a first controlled end of the first transistor M1 is connected with the first bit line bus BL, and a second controlled end of the first transistor M1 is connected with an input end of the first inverter INV1 and an output end of the second inverter INV2; a control end of the second transistor M2 is connected with the word line wl, a first controlled end of the second transistor M2 is connected with the first complementary bit line bus BL/, and a second controlled end of the second transistor M2 is connected with an output end of the first inverter INV1 and an input end of the second inverter INV2.

Referring to FIG. 6A, in some implementations, the memory cell XOR circuit comprises a third transistor M3, a fourth transistor M4, a fifth transistor M5, a sixth transistor M6, a seventh transistor M7, an eighth transistor M8, a ninth transistor M9, and a tenth transistor M10, wherein a first controlled end of the third transistor M3 is connected with a first power source, its second controlled end is connected with a first controlled end of the fourth transistor M4, a second controlled end of the fourth transistor M4 is connected with a first controlled end of the fifth transistor M5, a second controlled end of the fifth transistor M5 is connected with a first controlled end of the sixth transistor M6, a second controlled end of the sixth transistor M6 is connected with a second power source, a first controlled end of the seventh transistor M7 is connected with the first power source, its second controlled end is connected with a first controlled end of the eighth transistor M8, a second controlled end of the eighth transistor M8 is connected with a first controlled end of the ninth transistor M9, a second controlled end of the ninth transistor M9 is connected with a first controlled end of the tenth transistor M10, a second controlled end of the ninth transistor M10 is connected with the second power source, a control end of the third transistor M3 and a control end of the ninth transistor M9 are both connected with one end of a cross coupled inverter (the output end of the first inverter INV1 and the input end of the second inverter INV2), a control end of the seventh transistor M7 and a control end of the fifth transistor M5 are both connected with the other end of the cross coupled inverter (the input end of the first inverter INV1 and the output end of the second inverter INV2), a control end of the fourth transistor M4 and a control end of the sixth transistor M6 are both connected with the first bit bus BL, a control end of the eighth transistor M8 and a control end of the tenth transistor M10 are both connected with the first complementary bit line bus BL/, the second controlled end of the fourth transistor M4, the first controlled end of the fifth transistor M5, the second controlled end of the eighth transistor M8, and the first controlled end of the ninth transistor M9 are all connected, and serve as the output end of the memory cell XOR circuit, wherein the third transistor M3, the fourth transistor M4, the fifth transistor M5, and the sixth transistor M6 are all PMOS transistors, while the seventh transistor M7, the eighth transistor M8, the ninth transistor M9, and the tenth transistor M10 are all NMOS transistors. The first power source is connected with the supply power source, and the second power source is connected with the ground.

Referring to FIG. 6B, in some implementations, the memory cell inverting circuit comprises a third inverter, wherein an input end of the third inverter is connected with one end of the cross coupled inverter (the output end of the first inverter INV1 and the input end of the second inverter INV2), and the output end is configured to output the data stored in the memory cell.

As shown in Table 1, taking a standard unit trigger as the content addressable memory (briefly referred to as a reference implementation) the memory cell as an example, the reference implementation has 9540 gate stage circuits (45898 NMOS transistors and 45851 PMOS transistors), with an area of approximately 0.10362 mm². At the same capacity as the reference implementation, a plurality of memory banks provided in an implementation of the present application serve as content addressable memories (briefly referred to as an implementation of the present application) of the memory cells, comprising 22205 NMOS transistors and 24975 PMOS transistors, with an occupied area of approximately 0.07, which is reduced by approximately 30% compared to the reference implementation.

TABLE 1

| | | number of | number of |
|---|---|---|---|
| | | NMOS | PMOS |
| | size area (mm²) | transistors | transistors |
| reference | 0.10362 | 45988 | 45851 |
| implementation | | | |
| implementation of | 0.07(reduced by | 22205 | 24975 |
| the present | 30%) | | |
| application | | | |

In an implementation of the present application, the time for write, read, and compare operations of the content addressable memory is optimized, and existing design rules (such as the design rules of SRAM memory cells and page buffers) can be adopted. If the process allows, compressing the area of the content addressable memory can provide a more reasonable plan layout for the digital back-end. The implementation difficulty of the plan layout is not high, the labor time cost is low, and it is conducive to improving the utilization rate of the back-end area and fully utilizing winding resources.

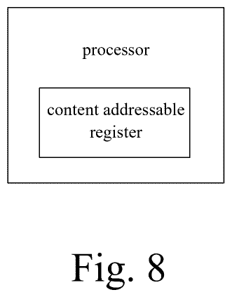

In a second aspect, an implementation of the present application provides a processor, as shown in FIG. 8, comprising: one or more content addressable memories as provided in the first aspect.

The processor can control the content addressable memory to perform functions such as reading and writing data, and retrieving input data. When the processor controls the content addressable memory to perform the function of retrieving input data, that is, when performing content addressing, the data can be compared with the stored data. If the data already exists in the content addressable memory, a matching success signal and a corresponding new data are output. Conversely, if the data is not saved in the content addressable memory, a matching failure signal is output. The processor is mainly configured to control the write, read, or compare operations on the data stored in the content addressable memory through the bus signal mbus. The bus signal mbus can comprise the bus clock signal mbus_clk, the bus data being address signal mbus_data_is_addr, the bus read enable signal mbus_rd_en, the bus write enable signal mbus_wt_en, and the bus write data signal mbus_wt_data<7:0>.

In some implementations, the processor may comprise one or more micro controller units (MCUs) for controlling the content addressable memory, a field programmable gate arrays (FPGA), a digital signal processors (DSP), an application specific integrated circuit (ASIC), a radio frequency integrated circuit (RFIC), etc. In some implementations, the processor comprises a microprocessor unit MCU. In this way, the content addressable memory hard macro module of MCU can be implemented.

For example, the content addressable memory comprises: a plurality of word lines; a bit line bus; a plurality of memory cells coupled with each of the word lines and the bit line bus; a timing control circuit configured to determine an operation mode according to a received bus command and generate a control signal for a corresponding operation mode, the operation mode comprising a read mode, a write mode, and a compare mode; an address line control circuit coupled with the timing control circuit, the word lines and the bit line bus and configured to activate a corresponding word line and the bit line bus based on the control signal; and a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode. The example details of the composition of the timing control circuit, the address line control circuit, and the processing and output circuit, as well as their signal processing processes, can be understood by referring to the corresponding implementations provided in the first aspect, and will not be repeated here.

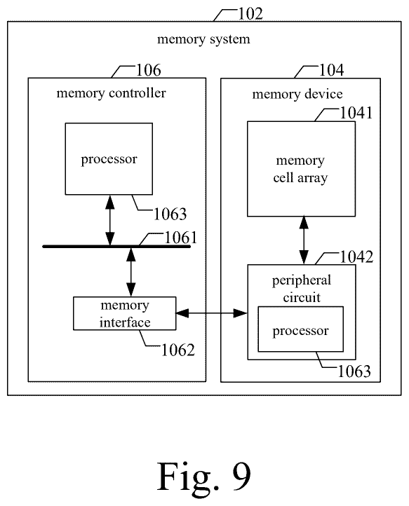

In the third aspect, an implementation of the present application provides a memory system, referring to FIG. 9, comprising: at least one memory device and a memory controller coupled with and controlling the memory device; wherein the memory device comprises: a memory cell array and a peripheral circuit coupled with and controlling the memory cell array; at least one of the peripheral circuit or the memory controller comprises one or more processors of any type provided in the second aspect.

In some implementations, the memory system 102 may comprise a memory controller 106 and a memory device 104. The memory controller 106 is configured to control the memory device 104 to perform operations such as read, write, and erase. The memory controller 106 may also be coupled with the memory device 104 in any suitable manner.

Memory controller 106 may comprise a processor 1063, a memory interface 1062, and a bus 1061, wherein the processor 1063 and the memory interface 1062 are coupled with the bus 1061. The processor 1063 communicates with the memory device 104 through the bus 1061. The memory interface 1062 is the connection interface between the memory controller 106 and the memory device 104, and is configured to achieve data transmission between the memory controller 106 and the memory device 104. The processor 1063 is configured to control the memory system 102 as a whole, and the example steps mentioned above performed by the memory controller are mainly performed and completed by the processor 1063. In some example implementations, the processor 1063 may be a central processing unit (CPU), a microprocessor (MCU), etc.

In some implementations, the memory device 104 may comprise a memory cell array 1041 and a peripheral circuit 1042 coupled to the memory cell array 1041, wherein the peripheral circuit 1042 may comprise a processor 1063.

Taking the memory cell array 1041 being a three-dimensional NAND memory cell array as an example, the memory cell is a NAND memory cell, and the memory cells are provided in the form of an array of memory strings, with each memory string extending vertically above the substrate (not shown). In some implementations, each memory string comprises a plurality of memory cells coupled in series and stacked vertically. Each memory cell can maintain a continuous analog value, such as voltage or charge, depending on the amount of electrons captured in the area of the memory cell. Each memory cell can be a floating gate type memory cell that comprises a floating gate transistor, or a charge capture type memory cell that comprises a charge capture transistor.

The peripheral circuit 1042 can be coupled to the memory cell array 1041 through bit lines, word lines, source lines, BSG lines, and TSG lines. The peripheral circuit 1042 may comprise any suitable analog, digital, and mixed signal circuit for promoting the operation of the memory cell array by applying at least one of voltage or current signals to each target memory cell through bit lines, word lines, source lines, BSG lines, and TSG lines, and sensing at least one of voltage or current signals from each target memory cell. The peripheral circuit 1041 may comprise various types of peripheral circuits formed using metal oxide semiconductor (MOS) technology. For example, the peripheral circuits comprise a page buffers/sensing amplifier, a column decoder/bit line driver, a row decoder/word line driver, a voltage generator, a control logic, a register, an interface, and a data bus.

In the fourth aspect, an implementation of the present application provides another content addressable memory, which comprises: a plurality of word lines wl extending along a first direction; a bit line bus BL and BL/extending along a second direction, wherein the first direction is perpendicular to the second direction; a plurality of memory banks cam unit to which the bit line bus and each of the word lines are coupled, wherein the plurality of memory banks are arranged along the first direction and each memory bank cam unit comprises a plurality of memory cells arranged along the second direction; a timing control circuit located between two adjacent memory banks and configured to determine an operation mode according to a received bus command and generate a control signal for a corresponding operation mode, wherein the operation mode comprise a read mode, a write mode, and a compare mode; a plurality of address line control circuits each coupled with the timing control circuit, located at an edge of one memory bank, and configured to activate a corresponding word line and the bit line bus based on the control signal; and a processing and output circuit coupled with the bit line bus and configured to: read out data stored in the memory cells from the bit line bus in the read mode; write data to be written from the bit line bus to the memory cells in the write mode, and compare data to be compared inputted from the bit line bus with the data already stored in the memory cells and output a compare result in the compare mode.

In each implementation of the present application, the first and second directions are represented as two orthogonal directions parallel to the substrate (or substrate structure) plane; a third direction is the stacking direction of the stacked structure, perpendicular to the substrate (or substrate structure) plane. Here and below, the first direction can be understood as the direction along which the word line extends, represented by the X direction in the accompanying drawings; the second direction can be understood as the direction along which the bit line extends, represented by the Y direction in the accompanying drawings; the third direction can be understood as the direction along which the first semiconductor structure and the second semiconductor structure are stacked, represented by the Z direction in the accompanying drawings.

In an implementation of the present application, the example details of the composition of the timing control circuit (comprising the word line decoding circuit), the address line control circuit, and the processing and output circuit, as well as their signal processing processes, can be understood by referring to the corresponding implementations provided in the first aspect, and will not be repeated here.

In some implementations, the plurality of memory banks comprise a first memory bank to a 2p-th memory bank arranged along the first direction, where p is a positive integer, the bit line bus comprises 2p parts each connected with one memory bank.

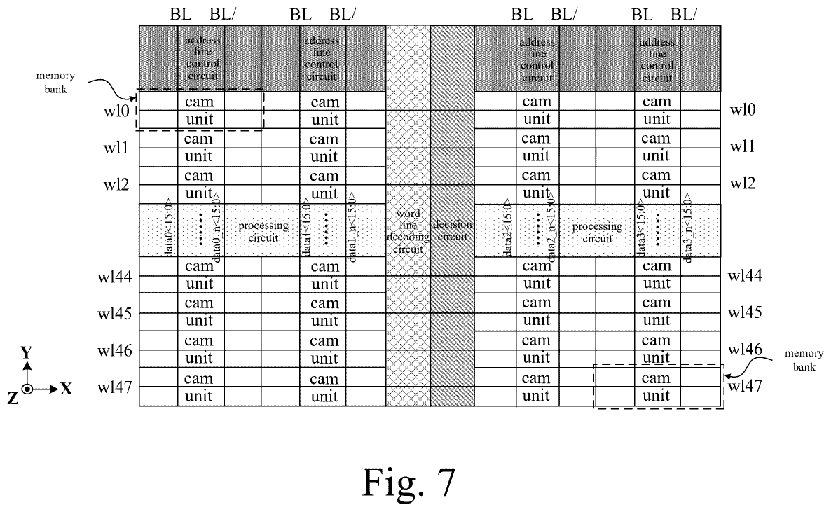

Referring to FIG. 7, for example, the plurality of memory banks comprise a first memory bank column to a fourth memory bank column arranged along the first direction, with each memory bank column comprising 48 memory banks arranged along the second direction, the bit line bus comprising four parts each respectively connected with one memory bank column. For example, the plurality of word lines comprise a first word line wl0, a second word line wl1, a third word line wl2, . . . a 45-th word line wl44, a 46-th word line wl45, a 47-th word line wl46, and a 48-th word line wl47, with each word line being coupled with all of four memory banks (from the first memory bank to the fourth memory bank) arranged along the first direction, and each part of the bit line bus being coupled with all of the 48 memory banks arranged along the second direction. For example, the data transmitted by each part of the bit line bus BL and BL/can be 16 bit data, for example, a part of the bit line bus BL and BL/transmits a data signal data0<15:0>/data0_n<15:0>.

Referring to FIGS. 4 and 7, each memory bank cam unit comprises 8 memory cells arranged along the second direction. The example composition of each memory cell can refer to the structure description of memory cells in FIGS. 6A and 6B.

In some implementations, the timing control circuit (not shown in FIG. 7) is located between the p-th memory bank and the (p+1)-th memory bank.

For example, the timing control circuit is located between the first memory bank column and the second memory bank column, and between the third memory bank column and the fourth memory bank column.

In some implementations, the word line decoding circuit of the timing control circuit is located between the p-th memory bank and the (p+1)-th memory bank. Referring to FIG. 7, for example, the word line decoding circuit is located between the second memory bank column and the third memory bank column.

In some implementations, the processing circuit of the processing and output circuit is located between the m-th memory bank row and (m+1)-th memory bank row, where m is a positive integer and m+1 is a multiple of 4, and the decision circuit of the processing and output circuits is located between p-th memory bank and the (p+1)-th memory bank. Referring to FIG. 7, for example, the processing circuit of the processing and output circuit is located between two adjacent memory banks along the second direction, and the decision circuit of the processing and output circuit is located between the second memory bank column and the third memory bank column.

In some implementations, the word line decoding circuit and the decision circuit are both located between the second memory bank column and the third memory bank column.

In some implementations, the address line control circuit is located at an edge of one memory bank column along the second direction, and the address line control circuit comprises 2p parts each respectively connected with a memory bank column. Referring to FIG. 7, for example, the address line control circuit comprises four parts arranged along the first direction, which are respectively coupled with the first memory bank column to the fourth memory bank column, and each part of the address line control circuit is coupled with all of 48 memory cells arranged along the second direction through each part of the bit line bus.

In some implementations, the memory bank comprises 2q memory cells arranged along the second direction, wherein the q is a positive integer, and the processing and output circuit comprises: a processing circuit located on one side of the memory cells, coupled with the bit line bus and the memory cells, and configured to: compare a first data to be compared inputted from the bit line bus with a second data already stored in the memory cells and output a data matching signal according to a compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and a decision circuit located between a q-th memory bank and a (q+1)-th memory bank, coupled with the processing circuit, and configured to receive the data matching signal and output a compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

Referring to FIGS. 4 and 5, for example, each memory bank cam unit comprises 8 memory cells arranged along the second direction. A memory bank corresponding to the first word line wl<0> (or the first word line wl0 shown in FIG. 7) comprises 8 memory cells arranged along the second direction, a memory bank corresponding to the second word line wl<2> (or the second word line wl1 shown in FIG. 7) comprises 8 memory cells arranged along the second direction, a memory bank corresponding to the third word line wl<2> (or the third word line wl2 shown in FIG. 7) comprises 8 memory cells arranged along the second direction, and a memory bank corresponding to the fourth word line wl<3> (or the fourth word line wl3 shown in FIG. 7) comprises 8 memory cells arranged along the second direction.

In an implementation of the present application, the example details of the composition of the processing circuit and the decision circuit, as well as their signal processing processes, can be understood by referring to the corresponding implementations provided in the first aspect, and will not be repeated here.

In some implementations, a 31 bit memory cell can be divided into four memory bank cam unit, each of which comprises eight memory cells arranged along the second direction, wherein two of the four memory banks cam unit can be configured to store old data signals pc_old<7:0>, as well as pc_old<14:8> and the identification signal pc_old<15>, and the other two of the four memory banks cam unit can be configured to store new data signal pc_new<7:0>, as well as pc_new<14:8> and one bit of default data pc_new<15> (data corresponding to the identification signal pc_old<15>, as shown in FIG. 4).

Regarding the content addressable memories provided in each implementation of the fourth aspect of the present application, for technical features not fully disclosed in the implementations of the present application, please refer to the content addressable memories in each implementation of the first aspect for understanding, and it will not be repeated here.

In each implementation of the present application, the time for write, read, and compare operations of the content addressable memories is optimized, and existing design rules (such as the design rules of SRAM memory cells and page buffers) can be adopted. If the process allows, compressing the area of content addressable memories can provide a more reasonable plan layout for the digital back-end. The implementation difficulty of the plan layout is not high, the labor time cost is low, and it is conducive to improving the utilization rate of back-end area and fully utilizing winding resources. The memory cells of the memory bank can be matched with a timing library, and the overall digital process conforms to the general digital back-end process, for example, being comparable with the digital process of such as a SRAM.

In the fifth aspect, an implementation of the present application provides an operation method for a content addressable memory comprising: a plurality of word lines, a bit line bus, a plurality of memory cells coupled with each word line and the bit line bus, a timing control circuit, an address line control circuit coupled with the timing control circuit, the word lines, and the bit line bus, and a processing and output circuit; wherein the operation method comprises: the timing control circuit determining an operation mode according to a received bus command and generating a control signal for a corresponding operation mode, the operation mode comprising a read mode, a write mode, and a compare mode; the address line control circuit activating a corresponding word line and the bit line bus based on the control signal; and the processing and output circuit reading out data stored in the memory cells from the bit line bus in the read mode, writing data to be written from the bit line bus to the memory cells in the write mode, and comparing data to be compared inputted from the bit line bus with data already stored in the memory cells and outputting a compare result in the compare mode.

In some implementations, the timing control circuit comprises: a timing generation circuit, an address counting circuit, and a word line decoding circuit; the address line control circuit activating a corresponding word line and the bit line bus based on the control signal, comprising: the timing generation circuit determining the operation mode according to the received bus command and generating the control signal and a reset signal for the corresponding mode according to the determined operation mode; the address counting circuit receiving a clock signal and the reset signal, and based on the reset signal, outputting a row address signal of a next row of a current processed row according to an edge change of the clock signal; and the word line decoding circuit receiving the row address signal outputted by the address counting circuit, decoding a row address in the row address signal, and outputting the decoded signal.

In some implementations, the address line control circuit comprises: a word line control circuit and a data conversion circuit; the address line control circuit activating a corresponding word line and the bit line bus based on the control signal, comprising: the word line control circuit receiving the decoded signal, and generating a word line drive signal according to the decoded signal to activate the corresponding word line; and the data conversion circuit receiving the control signal for the corresponding mode, and according to the control signal for the corresponding mode, performing a conversion of data bit on read data in the read mode, performing a conversion of data bit and differential processing on data to be written in the write mode, and performing differential processing on data to be compared in the compare mode.

In some implementations, the processing and output circuits comprise: a processing circuit and a decision circuit; the and comparing data to be compared inputted from the bit line bus with data already stored in the memory cells and outputting a compare result in the compare mode, comprising: the processing circuit comparing a first data to be compared inputted from the bit line bus with a second data already stored in the memory cells and outputting a data matching signal according to the compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and the decision circuit receiving the data matching signal and outputting the compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

In some implementations, the writing data to be written from the bit line bus to the memory cells in the write mode, comprising: the processing circuit writing, in the write mode, the data to be written after being processed by the data conversion circuit to the memory cells coupled with an n-th word line to an (n+3)-th word line within four clock cycles, wherein data bits of the data to be written are m bits, data bits of the data to be written after being processed by the data conversion circuit are 2m bits, a first bit to an m-th bit and an (m+1)-th bit to a 2m-th bit of the second data respectively represent data stored in an (n+2)-th word line and the (n+3)-th word line, and an m-th bit and an (m+1)-th bit of the third data respectively represent data stored in the n-th word line and an (n+1)-th word line, where the m and the n are both natural numbers, and the m is a multiple of 8.

In some implementations, the processing circuit comprises: a first processing circuit and a second processing circuit; the comparing a first data to be compared inputted from the bit line bus with a second data already stored in the memory cells and outputting a data matching signal according to the compare result in the compare mode, comprising: the first processing circuit comparing the first data with the second data and outputting a matching signal according to the compare result in the compare mode, wherein according to the first data being the same as the second data, the matching signal outputted is in the first logical state, and according to the first data being different from the second data, the matching signal outputted is in the second logical state; and the second processing circuit receiving the matching signal and outputting the data matching signal according to the matching signal, wherein according to the matching signal being in the first logical state, the data matching signal outputted is the third data, and according to the matching signal being in the second logical state, the data matching signal outputted is the fourth data, and each bit of data of the fourth data is in the second logical state.

In some implementations, the first processing circuit comprises: a plurality of memory cell XOR circuits and a first logic operation circuit; the first processing circuit comparing the first data with the second data and outputting a matching signal according to the compare result in the compare mode, comprising: each memory cell XOR circuit performing an XOR processing on data inputted from the bit line bus with data stored in the memory cells, and outputting an XOR result; and the first logic operation circuit receiving the XOR result outputted by each memory cell XOR circuit corresponding to the memory cells coupled with an (n+2)-th word line to an (n+3)-th word line, and performing a first logic operation on each XOR result to generate the matching signal.

In some implementations, the second processing circuit comprises: a plurality of memory cell inverting circuits and a second logic operation circuit; the second processing circuit outputting the data matching signal according to the matching signal, comprising: each memory cell inverting circuit performing an inverting processing on the data stored in the memory cells and outputting an inverted result; and the second logic operation circuit receiving the inverted result outputted by each memory cell inverting circuit corresponding to the memory cells coupled with the n-th word line to the (n+1)-th word line, and performing a second logic operation on each inverted result to generate the data matching signal.

The operation method of the content addressable memories provided in each implementation of the fifth aspect of the present application uses a content addressable memory that are the same or similar to the content addressable memory in each implementation of the first aspect mentioned above. For technical features not fully disclosed in the implementations of the present application, please refer to the content addressable memory in each implementation of the first aspect mentioned above for understanding, and it will not be repeated here.

It should be understood that the reference to “one implementation” or “an implementation” throughout the specification means that example features, structures, or characteristics related to the implementation are comprised in at least one implementation of the present application. Therefore, the terms “in one implementation” or “in an implementation” appearing throughout the entire specification may not necessarily refer to the same implementation. In addition, these example features, structures, or characteristics can be combined in any suitable way in one or more implementations. It should be understood that in various implementations of the present application, the size of the reference numbers of the above processes does not imply the order of execution. The execution order of each process should be determined by its function and internal logic, and should not constitute any limitation on the implementation process of the present application. The reference numbers of the above implementations are only for description and do not represent the advantages or disadvantages of the implementations.

The methods disclosed in several implementations of provided in the present application can be combined arbitrarily without conflict to obtain new method implementations.

The above are only example implementations of the present application, but the scope of protection of the present application is not limited thereto. Any skilled person familiar with the technical field can easily think of changes or replacements within the scope of the disclosed technology, which should be covered within the scope of protection of the present application.

What is claimed is:

1. A content addressable memory comprising:
a plurality of word lines;
a bit line bus;
a plurality of memory cells coupled with each of the word lines and the bit line bus;
a timing control circuit configured to determine an operation mode according to a received bus command and generate a control signal for a corresponding operation mode, the operation mode comprising one of a read mode, a write mode, or a compare mode;
an address line control circuit coupled with the timing control circuit, the word lines and the bit line bus and configured to activate a corresponding word line and the bit line bus based on the control signal; and
a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

2. The content addressable memory according to claim 1, wherein the timing control circuit comprises:
a timing generation circuit configured to determine the operation mode according to the received bus command and generate the control signal and a reset signal for the corresponding mode according to the determined operation mode;
an address counting circuit coupled with the timing generation circuit and configured to receive a clock signal and the reset signal, and based on the reset signal, output a row address signal of a next row of a current processed row according to an edge change of the clock signal; and
a word line decoding circuit coupled with the address counting circuit and configured to receive the row address signal outputted by the address counting circuit, decode a row address in the row address signal, and output the decoded signal.

3. The content addressable memory according to claim 2, wherein the address line control circuit comprises:
a word line control circuit coupled with the word line decoding circuit and configured to receive the decoded signal and generate a word line drive signal according to the decoded signal to activate the corresponding word line; and
a data conversion circuit configured to receive the control signal for the corresponding mode, and according to the control signal for the corresponding mode, perform a conversion of data bit on read data in the read mode, perform a conversion of data bit and differential processing on data to be written in the write mode, and perform differential processing on data to be compared in the compare mode.

4. The content addressable memory according to claim 1, wherein the processing and output circuit comprises:
a processing circuit coupled with the bit line bus and the memory cells and configured to compare a first data to be compared inputted from the bit line bus with a second data already stored in the memory cells and output a data matching signal according to the compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and
a decision circuit coupled with the processing circuit and configured to receive the data matching signal and output the compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

5. The content addressable memory according to claim 4, wherein the processing circuit is further configured to:
in the write mode, write the data to be written after being processed by a data conversion circuit to the memory cells coupled with an n-th word line to an (n+3)-th word line within four clock cycles, wherein data bits of the data to be written are m bits, data bits of the data to be written after being processed by the data conversion circuit are 2m bits, a first bit to an m-th bit and an (m+1)-th bit to a 2m-th bit of the second data respectively represent data stored in an (n+2)-th word line and the (n+3)-th word line, and an m-th bit and an (m+1)-th bit of the third data respectively represent data stored in the n-th word line and an (n+1)-th word line, where the m and the n are both natural numbers, and the m is a multiple of 8.

6. The content addressable memory according to claim 5, wherein the processing circuit comprises:
a first processing circuit coupled with the bit line bus and the memory cells and configured to compare the first data with the second data and output a matching signal according to the compare result in the compare mode, wherein according to the first data being the same as the second data, the matching signal outputted is in the first logical state, and according to the first data being different from the second data, the matching signal outputted is in the second logical state; and
a second processing circuit coupled with the first processing circuit and configured to receive the matching signal and output the data matching signal according to the matching signal, wherein according to the matching signal being in the first logical state, the data matching signal outputted is the third data, and according to the matching signal being in the second logical state, the data matching signal outputted is the fourth data, and each bit of data of the fourth data is in the second logical state.

7. The content addressable memory according to claim 6, wherein the first processing circuit comprises:
a plurality of memory cell XOR circuits each coupled with the bit line bus, wherein each memory cell XOR circuit is coupled with one of the memory cells and configured to perform XOR processing on data inputted from the bit line bus with the data stored in the memory cells, and output an XOR result; and
a first logic operation circuit coupled with the plurality of memory cell XOR circuits and configured to receive the XOR result outputted by each memory cell XOR circuit corresponding to the memory cells coupled with an (n+2)-th word line to an (n+3)-th word line, and performing a first logic operation on each XOR result to generate the matching signal.

8. The content addressable memory according to claim 6, wherein the second processing circuit comprises:
a plurality of memory cell inverting circuits, each of which is coupled with one of the memory cells and configured to perform a inverting processing on the data stored in the memory cells and output an inverted result; and
a second logic operation circuit coupled with the plurality of memory cell inverting circuits and configured to receive the inverted result outputted by each memory cell inverting circuit corresponding to the memory cells coupled with the n-th word line to the (n+1)-th word line, and perform a second logic operation on each inverted result to generate the data matching signal.

9. The content addressable memory according to claim 4, wherein the third data is storage address data corresponding to the second data.

10. The content addressable memory according to claim 1, wherein the bit line bus comprises a first bit line bus and a first complementary bit line bus, and the memory cell comprises: a first transistor, a second transistor, a first inverter, and a second inverter, wherein:
a control end of the first transistor is connected with the word line, a first controlled end of the first transistor is connected with the first bit line bus, and a second controlled end of the first transistor is connected with both of an input end of the first inverter and an output end of the second inverter; and
a control end of the second transistor is connected with the word line, a first controlled end of the second transistor is connected with the first complementary bit line bus, and a second controlled end of the second transistor is connected with both of an output end of the first inverter and an input end of the second inverter.

11. A processor comprising one or more content addressable memories, wherein the one or more content addressable memory comprises:
a plurality of word lines;
a bit line bus;
a plurality of memory cells coupled with each of the word lines and the bit line bus;
a timing control circuit configured to determine an operation mode according to a received bus command and generate a control signal for a corresponding operation mode, the operation mode comprising one of a read mode, a write mode, or a compare mode;
an address line control circuit coupled with the timing control circuit, the word lines and the bit line bus and configured to activate a corresponding word line and the bit line bus based on the control signal; and
a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

12. The processor according to claim 11, wherein the processor comprises a microprocessor unit (MCU).

13. A memory system comprising: at least one memory device and a memory controller coupled with and controlling the memory device, wherein:
the memory device comprises: a memory cell array and a peripheral circuit coupled with and controlling the memory cell array;
at least one of the peripheral circuit or the memory controller comprises one or more processors, the one or more processors comprising one or more content addressable memories, wherein the content addressable memory comprises:
a plurality of word lines;
a bit line bus;
a plurality of memory cells coupled with each of the word lines and the bit line bus;
a timing control circuit configured to determine an operation mode according to a received bus command and generate a control signal for a corresponding operation mode, the operation mode comprising one of a read mode, a write mode, or a compare mode;
an address line control circuit coupled with the timing control circuit, the word lines and the bit line bus and configured to activate a corresponding word line and the bit line bus based on the control signal; and
a processing and output circuit coupled with the bit line bus and configured to read out data stored in the memory cells from the bit line bus in the read mode, write data to be written from the bit line bus to the memory cells in the write mode, and compare data to be compared inputted from the bit line bus with data already stored in the memory cells and output a compare result in the compare mode.

14. The memory system according to claim 13, wherein the processor comprises a microprocessor unit (MCU).

15. The memory system according to claim 13, wherein the timing control circuit comprises:
a timing generation circuit configured to determine the operation mode according to the received bus command and generate the control signal and a reset signal for the corresponding mode according to the determined operation mode;
an address counting circuit coupled with the timing generation circuit and configured to receive a clock signal and the reset signal, and based on the reset signal, output a row address signal of a next row of a current processed row according to an edge change of the clock signal; and
a word line decoding circuit coupled with the address counting circuit and configured to receive the row address signal outputted by the address counting circuit, decode a row address in the row address signal, and output the decoded signal.

16. The memory system according to claim 15, wherein the address line control circuit comprises:
a word line control circuit coupled with the word line decoding circuit and configured to receive the decoded signal and generate a word line drive signal according to the decoded signal to activate the corresponding word line; and
a data conversion circuit configured to receive the control signal for the corresponding mode, and according to the control signal for the corresponding mode, perform a conversion of data bit on read data in the read mode, perform a conversion of data bit and differential processing on data to be written in the write mode, and perform differential processing on data to be compared in the compare mode.

17. The memory system according to claim 13, wherein the processing and output circuit comprises:
a processing circuit coupled with the bit line bus and the memory cells and configured to compare a first data to be compared inputted from the bit line bus with a second data already stored in the memory cells and output a data matching signal according to the compare result in the compare mode, wherein according to the first data being the same as the second data, the data matching signal outputted is a third data already stored in the memory cells, and according to the first data being different from the second data, the data matching signal outputted is a fourth data, and each bit of data of the fourth data is in a preset logical state; and
a decision circuit coupled with the processing circuit and configured to receive the data matching signal and output the compare result according to the data matching signal, wherein according to the data matching signal being the third data, the compare result outputted is in a first logical state which represents a successful comparison, and according to the data matching signal being the fourth data, the compare result outputted is in a second logical state which represents a failed comparison.

18. The memory system according to claim 17, wherein the processing circuit is further configured to:
in the write mode, write the data to be written after being processed by a data conversion circuit to the memory cells coupled with an n-th word line to an (n+3)-th word line within four clock cycles, wherein data bits of the data to be written are m bits, data bits of the data to be written after being processed by the data conversion circuit are 2m bits, a first bit to an m-th bit and an (m+1)-th bit to a 2m-th bit of the second data respectively represent data stored in an (n+2)-th word line and the (n+3)-th word line, and an m-th bit and an (m+1)-th bit of the third data respectively represent data stored in the n-th word line and an (n+1)-th word line, where the m and the n are both natural numbers, and the m is a multiple of 8.

19. The memory system according to claim 18, wherein the processing circuit comprises:
a first processing circuit coupled with the bit line bus and the memory cells and configured to compare the first data with the second data and output a matching signal according to the compare result in the compare mode, wherein according to the first data being the same as the second data, the matching signal outputted is in the first logical state, and according to the first data being different from the second data, the matching signal outputted is in the second logical state; and
a second processing circuit coupled with the first processing circuit and configured to receive the matching signal and output the data matching signal according to the matching signal, wherein according to the matching signal being in the first logical state, the data matching signal outputted is the third data, and according to the matching signal being in the second logical state, the data matching signal outputted is the fourth data, and each bit of data of the fourth data is in the second logical state.

20. The memory system according to claim 19, wherein the first processing circuit comprises:
a plurality of memory cell XOR circuits each coupled with the bit line bus, wherein each memory cell XOR circuit is coupled with one of the memory cells and configured to perform XOR processing on data inputted from the bit line bus with the data stored in the memory cells, and output an XOR result; and
a first logic operation circuit coupled with the plurality of memory cell XOR circuits and configured to receive the XOR result outputted by each memory cell XOR circuit corresponding to the memory cells coupled with an (n+2)-th word line to an (n+3)-th word line, and performing a first logic operation on each XOR result to generate the matching signal.
